(19) United States
(12) Patent Application Publication
(10) Pub. No.: US 2011/0288793 A1
(43) Pub. Date: Nov. 24, 2011

(54) EVENT IDENTIFICATION

(76) Inventors: Jose Manuel Sanchez-Loureda, London (GB); Adam Richard Westbrooke, Kent (GB)

(21) Appl. No.: 13/027,636

(22) Filed: Feb. 15, 2011

Related U.S. Application Data
(60) Provisional application No. 61/306,195, filed on Feb. 19, 2010.

(51) Int. Cl. G06F 19/00; G01F 1/00; G01R 21/00

(52) U.S. Cl. 702/45; 702/61; 702/62

(57) ABSTRACT

A method of identifying an event associated with consumption of a utility comprising the steps of generating a utility consumption profile from utility consumption data, the utility consumption data comprising a plurality of utility consumption values measured at a corresponding plurality of measurement points, and identifying an event within the utility consumption profile that matches the profile of an event stored in a database of utility consumption profiles. A computer implemented apparatus, a computer program code and an article of manufacture comprising a machine-readable storage medium and executable program instructions embodied therein, for carrying out the method are also provided.

### RELATED APPLICATION

The present invention claims priority of U.S. Provisional Application No. 61/306,195 filed Feb. 19, 2010, the contents of which are incorporated herein in their entirety.

### FIELD OF THE INVENTION

This invention relates to methods, systems, devices and computer code for identifying events associated with consumption of utilities, in particular consumption of gas, water and electricity, and using measured utility consumption data for applications such as analysis of household power consumption by an end-user or by a utility supplier, or monitoring occupancy and activity within a household.

### BACKGROUND

There is an ongoing and urgent need to reduce consumption of energy and water both for environmental and cost reasons.

A large proportion of the energy and water supplied by utilities suppliers is wasted as a result of inefficiencies such as use of electrical appliances that have poor efficiency or for behavioural reasons such as appliances that are left switched on and so consume electricity even when not in use, or excessive consumption of water. This leads to wastage and increased utilities costs. Moreover, with respect to electricity, electrical energy use in buildings accounts for a very large proportion of all carbon emissions. Demand for utilities can vary dramatically between identical buildings with the same number of occupants, and this suggests that reducing waste through behavioural efficiency is essential. Therefore, efforts are required to change the patterns of utilities use by consumers.

The utilities suppliers recognise three major obstacles to progress in this objective: a shortage of sources of competitive advantage, a lack of detailed understanding of their customers, and a lack of “touch points”, i.e. ways of interacting with the customers. Opportunities for differentiation revolve mainly around price and “green” issues, i.e. reduction of environmental impact. The utilities suppliers have very little information about their customers' behaviour since electricity, gas and water meters collect whole house data continuously and are read infrequently.

Meters to measure total consumption of utilities of a household are commonplace for each of gas, electricity and water, however this total is not useful in identifying areas in which efficiencies may be possible (for brevity, we refer herein to a “household”, however it will be appreciated that the present invention is not limited to a domestic house but may be applied to any domestic, workplace or other setting that receives its own discrete utilities supplies, in particular mains electricity supply from an electricity grid; water supply; and/or gas supply.).

A clamp-on energy meter for monitoring the consumption of electricity supplied on a cable is disclosed in WO 2008/142431. While a meter of this type is beneficial in assisting a user to review energy consumption patterns, there remains a need for yet more detailed information on user consumption of utilities supply, in particular electricity and water.

It is therefore an object of the invention is to provide technical means for generating detailed information on utilities consumption within a household.

### SUMMARY OF THE INVENTION

The present inventors have found that it is possible to identify events associated with consumption of utilities (for example the filling of a sink with water or the switching on of a kettle) based on data derived from measurements of utility consumption.

For instance, operation of any given electrical appliance makes a series of power demands in a certain order, giving it a unique power “signature” associated with operation of that appliance. Data derived from measurements of the changes in power demand of a household over time can be analysed to identify events associated with operation of known appliances in order to match the electricity consumption of appliances in a household to known appliances and to provide detailed information of energy consumption associated with each identified appliance.

“Appliance” as used herein means any device that consumes one or more supplied utility, in particular gas, electricity or water.

Accordingly, in a first aspect the invention provides method of identifying an event associated with consumption of a utility comprising the steps of:

generating a utility consumption profile from utility consumption data, the utility consumption data comprising a plurality of utility consumption values measured at a corresponding plurality of measurement points; and
identifying an event within the utility consumption profile that matches the profile of an event stored in a database of utility consumption profiles.

Optionally, the utility is selected from gas, electricity and water.

Optionally, the utility is electricity and the measured electricity consumption data includes data of real power, data of reactive power, or data of both reactive and real power.

Optionally, the utility is water.

Optionally, the plurality of measurement points are a plurality of time points with intervals therebetween.

Optionally, the intervals between time points is in the range 0.01-60 seconds.

Optionally, generating the utility consumption profile comprises the step of determining a gradient of rate of change of utility consumption between consecutive measurement points; identifying measurement points at which a change in gradient exceeds a predetermined threshold; and storing in the utility consumption profile the utility consumption value at measurement points where the threshold is exceeded.

Optionally, matching of the utility consumption profile comprises representing the utility consumption profile in the form of a matrix and matching the contents of the matrix to utility consumption event profile matrices stored in the database.

Optionally, one or more entries in the matrix are weighted.

Optionally, a match is identified if the extent of matching between a series of entries in a measured matrix and a matrix stored in the database exceeds a threshold value.

Optionally, the utility consumption profile is disaggregated.

Optionally, the generated utility consumption profile is analysed to identify an event matching a utility consumption profile stored in the database and associated with operation of an appliance that consumes the utility.

Optionally, the generated and stored utility consumption profiles are electricity consumption profiles and the appliance is an electrical appliance.

Optionally, the utility consumption data is one of gas, electricity and water consumption data, and the identity of the event is verified using at least one of the other of gas, electricity and water consumption data.

Optionally, the identity of the event is verified using measured data other than utility consumption data.

Optionally, the measured data is temperature data.

Optionally, the identity of the event is verified using probability data.

Optionally, the identity of an event associated with an appliance is verified using data supplied by an appliance user.

In a second aspect, the invention provides a computer program code which when run on a computer causes the computer to perform the method according to the first aspect.

In a third aspect, the invention provides a carrier medium carrying computer readable code which when run on a computer causes the computer to perform the method according to the first aspect.

In a fourth aspect, the invention provides a computer program product comprising computer readable code according to the third aspect.

In a fifth aspect, the invention provides computer-implemented event identification apparatus comprising:

a profile generator for generating a utility consumption profile from utility consumption data, the utility consumption data comprising a plurality of utility consumption values measured at a corresponding plurality of time points; and
an event identifier for identifying an event within the utility consumption profile that matches the profile of an event stored in a database of utility consumption profiles.

In a sixth aspect, the invention provides an article of manufacture comprising:

a machine-readable storage medium; and
executable program instructions embodied in the machine readable storage medium that when executed by a programmable system causes the system to perform the function of identifying an event associated with consumption of a utility comprising the steps of:
generating a utility consumption profile from utility consumption data, the utility consumption data comprising a plurality of utility consumption values measured at a corresponding plurality of measurement points; and
identifying an event within the utility consumption profile that matches the profile of an event stored in a database of utility consumption profiles.

In order to identify an event as per the first aspect of the invention, a series of changes in utility consumption over time recorded in the electricity consumption data may be used to identify a “signature” that can be matched to signatures of known events stored in a database. In the case of electricity consumption data, for example, this “signature” may be a series of changes in power demand over time that is indicative of operation of an electrical appliance. For example, a the event of a refrigerator being switched on may have a characteristic power demand signature that could be used to identify the presence of that refrigerator in the household.

Accordingly, in a seventh aspect, the invention provides a method of compressing utility consumption data comprising a plurality of utility consumption values at a corresponding plurality of measurement points comprising: determining a gradient of change of utility consumption value between each consecutive measurement point, and identifying and storing measurement points where a change in the gradient exceeds a threshold value.

Optionally according to the seventh aspect, the utility consumption data is electrical power demand data; the plurality of utility consumption values are power values; and the plurality of measurement points regularly spaced time points.

Optionally, the electrical power demand data is real power and/or reactive power.

In an eighth aspect, the invention provides a device for compressing utility consumption data comprising a plurality of utility consumption values at a corresponding plurality of measurement points, the device comprising:

means for determining a gradient of change of utility consumption value between each consecutive measurement point, and
means for identifying and storing measurement points where a change in the gradient exceeds a threshold value.

Optionally according to the eighth aspect, the device further comprises means for measuring utility consumption to generate utility consumption data.

Optionally, the device further comprises means for wired or wireless transmission of compressed utility consumption data to a data processor.

In a ninth aspect, the invention provides an integrated circuit configured to perform the steps according to the seventh aspect of the invention.

In a tenth aspect, the invention provides computer program code which when run on a computer causes the computer to perform the method according to the seventh aspect of the invention.

In an eleventh aspect, the invention provides a computer program product carrying program code according to the tenth aspect.

In a twelfth aspect, the invention provides a carrier medium carrying computer readable code which when run on a computer causes the computer to perform the method according to the seventh aspect of the invention.

In a thirteenth aspect, the invention provides an article of manufacture comprising:

a machine-readable storage medium; and
executable program instructions embodied in the machine readable storage medium that when executed by a programmable system causes the system to perform the function of compressing utility consumption data, comprising the steps of:
determining a gradient of change of utility consumption value between each consecutive measurement point, and
identifying and storing measurement points where a change in the gradient exceeds a threshold value.

In a fourteenth aspect, the invention provides a method of identifying an appliance comprising the steps of:
identifying a candidate appliance by matching utility consumption of known appliances stored in a database to measured consumption of a first utility; and
comparing a known property of the candidate appliance to a property of the measured appliance to verify the accuracy of the match.

Optionally according to the thirteenth aspect, the known property of the appliance is the utility consumption of a second utility, the second utility being different from the first utility.

Optionally according to the thirteenth aspect, the first and second utilities are selected from water, gas and electricity.

Optionally according to the thirteenth aspect, the known property of the candidate appliance is probability data associated with the candidate appliance.

The known property of a candidate appliance may be a directly measured property of the appliance (e.g. temperature of the appliance when in use) or a property derived from measurements such as data derived from consumption of electricity, gas or water supplied to the household when the appliance is in use, as described above.

The known property is not necessarily a property of the appliance when in use. In particular, the known property may be a probability of a candidate appliance being present, for example based on inferred or socio-economic data.

In a fifteenth aspect, the invention provides computer implemented apparatus comprising:

means for identifying a candidate appliance by matching utility consumption of known appliances stored in a database to measured consumption of a first utility;
means for identifying a second property of an appliance; and
means for comparing a known property of the candidate appliance to a property of the measured appliance to verify the accuracy of the match.

In a sixteenth aspect, the invention provides an article of manufacture comprising:

a machine-readable storage medium; and
executable program instructions embodied in the machine readable storage medium that when executed by a programmable system causes the system to perform the function of identifying an appliance, comprising the steps of:
identifying a candidate appliance by matching utility consumption of known appliances stored in a database to measured consumption of a first utility; and
comparing a known property of the candidate appliance to a property of the measured appliance to verify the accuracy of the match.

In a seventeenth aspect, the invention provides computer program code which when run on a computer causes the computer to perform the method according to the fourteenth aspect.

In a eighteenth aspect, the invention provides a computer program product carrying program code according to the seventeenth aspect.

In a nineteenth aspect, the invention provides a carrier medium carrying computer readable code which when run on a computer causes the computer to perform the method according to the fourteenth aspect.

The invention further provides systems, devices, computer-implemented apparatus and articles of manufacture for implementing any of the aforementioned aspects of the invention; computer program code configured to perform the steps according to any one of the aforementioned methods; a computer program product carrying program code configured to perform the steps according to any one of the aforementioned methods; and a computer readable medium carrying the computer program.

### DESCRIPTION OF FIGURES

The invention will now be described in detail with reference to the following figures in which:

FIG. 1 is a flowchart illustrating measuring, analysis and matching steps according to the method of the invention.

FIG. 2 illustrates the identification of “corners” in electricity consumption data

FIG. 3 illustrates schematically the identification of missing corners

FIG. 4 is a flowchart illustrating the corner detection algorithm

FIG. 5 illustrates a matching step according to the invention

FIG. 6 schematically illustrates apparatus for implementation of the method of the present invention.

FIG. 7 schematically illustrates a event identification device

FIG. 8 is a simplified functional block diagram of a computer that may be configured as a host or server, for example, to function as the event identification device in the system of FIG. 7; and

FIG. 9 is a simplified functional block diagram of a personal computer or other work station or terminal device.

### DETAILED DESCRIPTION OF THE INVENTION

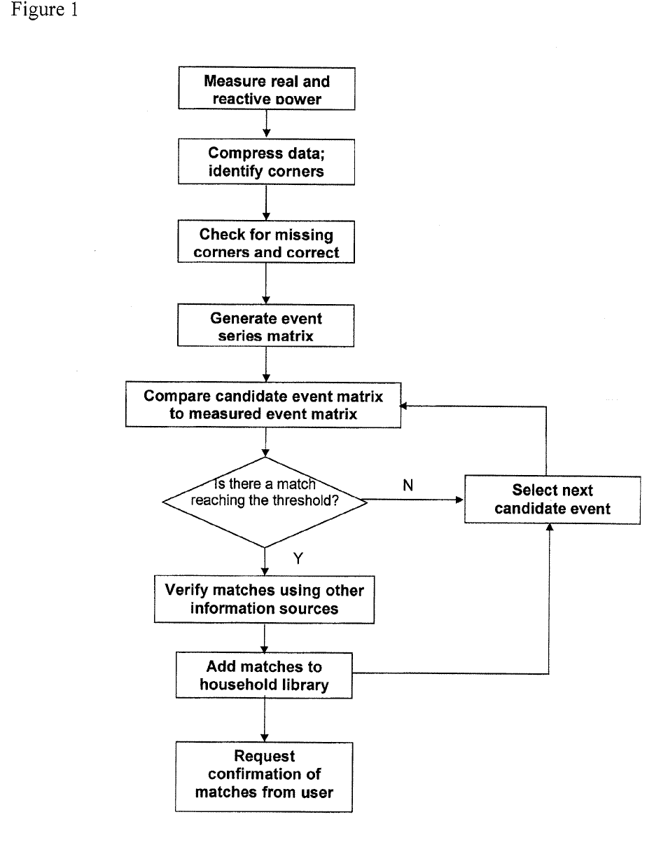

The method of the invention is illustrated in FIG. 1 with respect to electricity consumption, and may be divided into three broad steps: (1) Measurement of electrical data at regular measurement points, in particular at regularly spaced time points; (2) Creation of an electricity consumption profile based in particular on changes in electricity demand, in particular power, between measurement points; and (3) Matching events within the measured electricity consumption profile to energy consumption profiles stored in a database and associated with a known event.

Each of these steps is described in more detail below. While the invention is described hereinafter primarily with respect to measurement and analysis of electricity consumption, in order to identify events and appliances associated with consumption of electricity, it will be appreciated that the same steps may equally be taken using data relating to consumption of gas or water utilities.

### Measurement

A sensing device such as a clamp-on energy meter as disclosed in WO 2008/142431 measures real and reactive power at fixed time points. A higher frequency of measurement will obviously yield more electricity consumption data, which in turn increases the likelihood of an accurate match when the profile generated from the measured data is compared to stored electricity consumption profiles. Typically, electricity consumption is measured at least once every second. This is captured as two separate streams of data (“real power” and “reactive power” as used herein have the meanings as understood by a skilled person in the art in relation to power supplied to a load from an alternating current source). One advantage of measuring both real and reactive power is that, between them, it is possible to measure power demand of most or all appliances. For instance, it may be difficult or impossible to obtain a meaningful measurement of real power for certain appliances such as set-top boxes, however reactive power for these devices can be measured.

Also measured is energy consumed at fixed time intervals, typically every second. From this can be calculated a running total of energy consumed over longer periods, for example every 512 seconds, 2048 seconds or 86,400 seconds (24 hours). These measurements can also be used to show the maximum and minimum energy usages over one of these longer time periods. Although these energy consumption measurements are not used in generating an “event matrix” as described in more detail below, this information is nevertheless beneficial in providing a detailed picture of energy consumption over the course of an extended time period during which various appliances may be switched on and off.

Consumption of water and gas can be measured using techniques that are well known to the skilled person, for example based on use of water and gas meters. Water and gas consumption, in particular water consumption, may be measured at a lower rate, for example at least once every 300 seconds or at least once every 60 seconds, in order to generate water consumption data that may be used to identify events associated with consumption of water. The rate of flow of water or gas at each time interval may be measured, along with the total volume consumed over time in a manner analogous to power and energy measurements of electricity consumption. Additionally or alternatively, water and gas consumption may be measured at measurement points after intervals of volume consumption rather than intervals of time, for example a measurement of time elapsed for each unit volume (e.g. litre) of water to be consumed.

### Compression

As shown in FIG. 1, the electricity consumption data relating to real and reactive power is fed into a compression algorithm, referred to hereinafter as a “corner detection algorithm”.

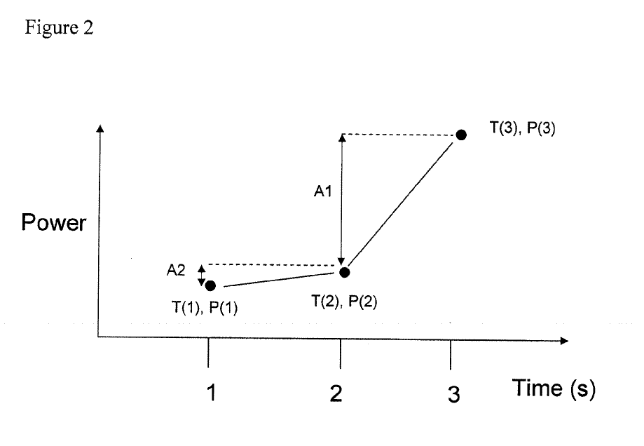

The operation of the corner detection algorithm is illustrated schematically in FIG. 2. The compression algorithm identifies “corners” in power demand by identifying differences in the gradient representing rate of change in power from one time point to the next. A point at which there is change in gradient between two time intervals (identified as T(2), P(2)) is marked as a “corner” if that change is greater than a predetermined threshold. This is done by measuring the power difference between points T(3), P(3) and T(2), P(2) and between T(2),P(2) and T(1),P(1) to give values A1 and A2 respectively. If the difference B between A1 and A2 exceeds a predetermined value Tol1 then a corner is marked.

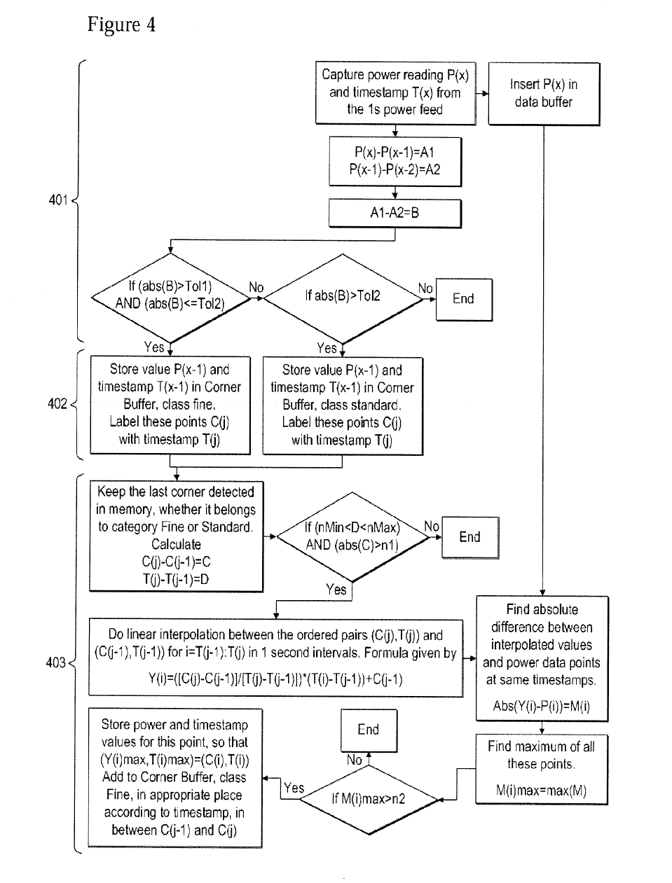

The operation of the algorithm is illustrated in more detail in FIG. 4 in which:

T(x), T(i) and T(j) represent 32 Bit timestamps
C(x), C(j) and Y(i) represent 16 Bit power readings at a corner
Tol1, Tol2 represent integer numerical values (0-100)
A1, A2, B represent 16 Bit power reading differences
n1, nMax, nMin, n2 represent 16 Bit numerical values
M(i), M(i)max represent 16 Bit numerical values

Section 401 of FIG. 4 illustrates identification of corners as described above with reference to FIG. 2.

Section 402 of FIG. 4 illustrates the classification of corners into “Standard” and “Fine” classes depending, respectively, on whether B is greater than predetermined values Tol1 and Tol2 or greater than Tol1 only.

The skilled person will understand how to select the value of the threshold for marking a point as a corner, and the specific value will vary from case to case. In order to avoid incorrect identification of background noise in identification of a corner, only those points having a signal strength greater than a minimum multiple of background noise strength may be used in corner identification.

By measuring a plurality of these corners in the electricity consumption data, an electricity consumption profile is generated, representing a series of events associated with changes in power demand from which appliances may be identified using known “signature” profiles of those appliances.

### Correction

The electricity consumption profile generated as described above with respect to FIG. 2 and sections 401 and 402 of FIG. 4 contains the majority of corners, however a correction may be applied to identify one or more corners that may have been missed.

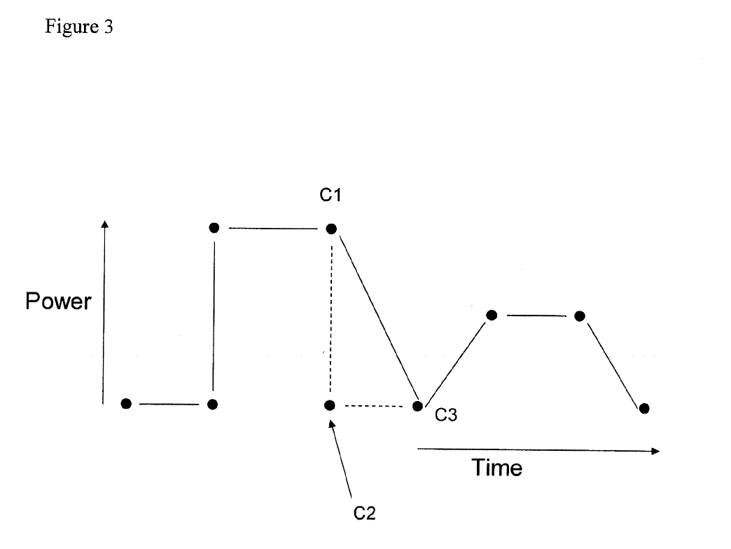

This is illustrated in FIG. 3 which shows a corner C(2) between corners C(1) and C(3) that has been missed by the corner detection algorithm.

A missing corner may be identified if both the power difference (power at C1−power at C2) and the time difference (time at C1−time at C2) fall outside defined values as illustrated in section 403 of FIG. 4.

In this event, a linear interpolation may be conducted to identify any missing corners, as illustrated in Section 403 of FIG. 4. Referring to FIG. 3, missing corner C3 should be inserted at the point giving the most acute angle between lines C1-C2 and C2-C3.

### Matching

The electricity consumption profile may be represented in the form of a matrix representing the various events that occurred during the period that electricity consumption was measured. For example, if a refrigerator was switched on during the period of electricity consumption measurement then the signature profile associated with that event may be as follows:

$$Time \to \begin{matrix} & \begin{matrix}Event \\ Star t\end{matrix} & & & & \begin{matrix} \\ Finish\end{matrix} \\ ( & 1 & 0 & 4 & 7 & )\end{matrix}$$

The electricity consumption profile may be analysed to determine if it contains a signature event series stored in a database indicative of a refrigerator switching on. The event series of one or more candidate appliances stored in a database may be compared to the measured profile in order to identify whether the measured profile contains an event series matching that of a refrigerator switching on.

The matrix below illustrates the output from matching of a number of candidate events to the above event matrix. In this case, the first row shows a good match between the measured profile and the event to which it was compared. The further rows show poorer matches, indicating that the measured event probably corresponds to the candidate event of the first row.

$$Time \to \begin{matrix} & \begin{matrix}Event \\ Start\end{matrix} & & & & \begin{matrix} \\ Finish\end{matrix} \\ ( & \begin{matrix}1 \\ 1 \\ 0 \\ 0\end{matrix} & \begin{matrix}1 \\ 0 \\ 1 \\ 0\end{matrix} & \begin{matrix}1 \\ 1 \\ 0 \\ 0\end{matrix} & \begin{matrix}1 \\ 1 \\ 1 \\ 1\end{matrix} & )\end{matrix}$$

In this way, the probability of a given appliance being present in the household can be determined. If this probability exceeds a threshold value then that appliance is assumed to be present in the household. If on the other hand the probability falls below a threshold then that appliance is assumed not to be in the household. For instance, an event series represented by one row of the matrix may form a good match with the event series of an appliance in the database, and so the data in that row can be attributed to an identified appliance.

Parameters associated with an event that may be used to determine a match include the following:

Minimum change in power
Maximum change in power
Peak power minimum
Peak power maximum
Minimum power change time after time 0
Maximum power change time after time 0
Minimum time to next event
Maximum time to next event

Power threshold (the minimum power change between measurement points). These parameters may be determined by measuring event series of known appliances. Each of these parameters may be determined for each specific make and model of an appliance and/or may be a generic parameter to be used for any member of a genus of appliances (for example, the genus of washing machines) wherein the generic parameter is determined by measuring a plurality of devices within a genus and determining a parameter value that is applicable to most or all members of the genus.

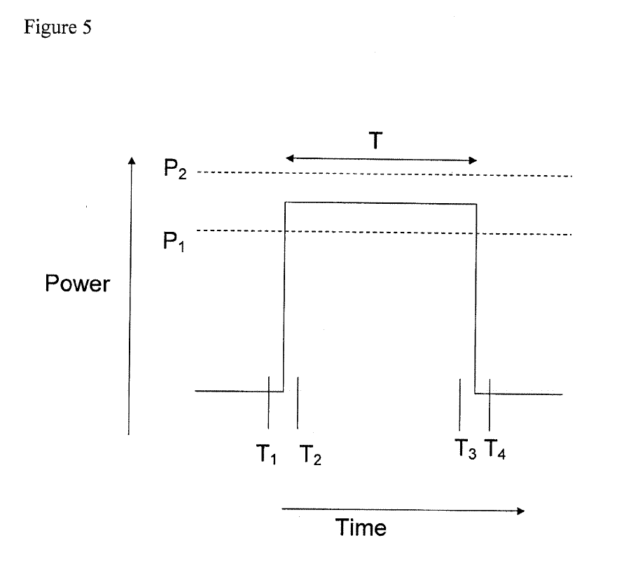

This is illustrated schematically in FIG. 5, which illustrates a matching step wherein a match may be based on one or more of: an event occurring at a first time point between T1 and T2; the event having an associated power falling between P1 and P2; and a time T until the next event occurring at a time point between T3 and T4.

Weighting may be applied to the event matrix in order to improve the accuracy of matching. For example, one entry within the event matrix may be associated with high power consumption that may be given higher weighting than other entries that may be lower power, and that may be easier to confuse with background electricity consumption.

For any given event, the event series contained within the database comprises a plurality of entries showing at least one power change indicative of an event. Typically, the event comprises a plurality of changes in power value, the magnitude and duration of which can be used to generate a signature event series for that event. However, it is possible that a single change in power value could be stored as an event series within the database, in particular if the magnitude of that change is large enough to provide a distinctive event series.

Different techniques can be used in identification of different appliance genera. Suitable techniques for any given genus will be apparent to the skilled person following measurement and analysis of event series for known appliances within each genus.

For example, a kettle profile can be characterised by an on event, followed by a similar off event after a defined amount of time has elapsed (this amount of time is defined by parameters derived from typical kettle usage). Since kettles may be of different sizes, a broad search in on event magnitudes and duration is firstly carried out in the electricity consumption data for the whole household, yielding matrices with all appliances satisfying those parameters. These results, since they tend to be different instances of appliance usage, tend to form clusters when one plots the on event power magnitude against the duration in time between their respective on and off events. Then a finite mixtures model based clustering method may be used to automatically select the most likely candidate kettle cluster. Other attributes can be calculated from this information, such as an estimate of the amount of water boiled in each kettle use.

On the other hand, in the case of a washing machine, a plurality of discrete events can be identified in relation to operation of a washing machine, such as heating and spin cycle events. Individually, these are simple on/off events, which can be detected individually. Independent analysis of these individual components can then be combined and further analysed to identify a washing machine. Using this information, one can then use a similar method of clustering to determine which is the most likely heating element which corresponds to the washing machine, in order to calculate the energy used, and temperature of the wash cycle, for example.

Thus, in one embodiment an appliance may be detected by identifying an event associated with only part of the operation of that appliance. In particular, by measurement of event series associated with known devices, certain events may be identified as being more prominent than other events (for example due to a power change associated with that event that is particularly characteristic of the appliance genus in question) and may be used as the primary event in the process of appliance detection. Other events determined to be associated with the detected appliance may be used to verify the accuracy of the match and/or to determine parameters such as the amount of energy used by the appliance.

Thus, using information derived from measurement and analysis of electricity consumption profiles of known appliances, the skilled person may identify mathematical techniques suitable for identification of any given appliance or any appliance genus such as the finite mixtures model based clustering technique described above, or other techniques such as hidden Markov models.

In this way, use of known appliance event series for common household appliances allows estimation of most or all of the constituents of measured electricity consumption data for the entire household, and allows for disaggregation of signals associated with operation of more than one appliance.

The appliance may be any appliance to which power is supplied via mains electricity including but not limited to kitchen appliances such as fridges, freezers, microwave ovens, electrical cookers, washing machines, tumble dryers and dishwashers; leisure appliances such as televisions, hi-fis, set-top boxes, video or dvd players or recorders; game consoles; and other appliances such as electric boilers, central heating water pumps, pool pumps, air conditioning units, personal computers, vacuum cleaners, irons and lawn mowers.

Following an initial match of a measured event series to an event series stored in the database associated with a specific appliance, the confidence in accuracy of identification of that appliance may be increased by looking for one or more further event series corresponding to other events associated with operation of that appliance. Furthermore, certain appliances may have event series that occur cyclically, for example a refrigerator. If a match is identified for such an appliance then the match may be verified by checking for this cyclic pattern.

A detected event is not necessarily associated with operation of an appliance. For instance, a power cut or other abnormality in the power supply may possess an identifiable event series.

### Databases

As set out above, the event series of one or more candidate appliances stored in a database may be compared to the measured profile in order to identify whether the measured profile contains a profile matching that of a stored event series.

One or more databases may be checked for the purpose of event matching, including but not limited to:

i) A specific appliance database comprising event series associated with specific appliances, such as event series for a plurality of different makes and models of appliances. A database of this type has the advantage of being able to determine very specifically the make and model of devices present in a household.
ii) A generic appliance database comprising event series that are common to genera of devices. For example, the genus of washing machines will all have similar event series such as event series associated with heating or spin cycles, and those similar event series may be used to create a single, generic event series for the event in question. By measuring event series for a plurality of different makes and models of devices it is possible to identify appliance genera and at least one generic event series common to each member of an appliance genus. Use of a generic database of this type has the advantage of being smaller than a database containing event series for a plurality of makes and models of appliances within each genus, and also allows for faster matching.

Initially, a generic event series may be generated using only two event series associated with two different appliances of a common genus, such as the spin cycle of two different models of washing machine. In order to increase matching accuracy for a given event or appliance, each generic event series may be changed over time as event series for known appliances within the same appliance genus are measured.

iii) A household database specific to the household for which utility consumption data is analysed. Following the initial identification of events occurring within a household and the associated appliances, a database specific to that household may be created, and the contents of this database may be used to quickly identify future events based on previously measured occurrences of those events or previous identification of the associated appliance. The speed and accuracy of event matching using a household database may increase as utility consumption data is measured over time. Use of the household database in this way allows for real-time identification of events and appliances, which may be communicated to a system user either local to or remote from the household.

### Multiple Data Sources

A measured event may be identified based on probability of a match derived from the event matrix alone, however one or more further data sources may be taken into account in order to verify the match (for the avoidance of doubt, “verify” as used herein means increasing the confidence in a match being correct or increasing the calculated probability of a match being correct, and does not necessarily mean determining with absolute certainty that a match is correct). It will be appreciated that any sensor within a household may provide further this further data, including but not limited to the following:
Water consumption for appliances such as washing machines. For example, if an event associated with a washing machine is identified as a match then the confidence in an accurate match may be increased by determining if water was consumed at the same time as electricity was consumed for the relevant event series. In a more sophisticated analysis, measurement of a household's water demand over time may be used to identify water consumption signatures of appliances present in the household that can be matched to known water consumption signatures of known appliances. For instance, a water consumption signature may be based on changes in rate of water consumption with time in a manner analogous to the electrical appliance signatures described above.
Gas consumption for appliances that consume both gas and electricity in the same way as water consumption described above.
Temperature of appliances that change temperature with use, for example refrigerators, freezers and boilers.
Temperature difference between household ambient temperature and external temperature.
Movement sensors such as passive infrared sensors to determine if a household is occupied. For example if no movement is sensed within the household then it may be inferred that the household is empty in which case the confidence in accuracy of a match for an appliance that is used during occupancy, such as a television, is reduced. On the other hand, the confidence in accuracy of a match for other appliances, such as refrigerators, may remain unchanged. The use of movement sensor data to verify a match may take into account the time at which an event series is detected (e.g. day or night) and/or the length of time since a movement was last sensed.
Probability data in particular data derived from:
   (i) Inferred data. If certain appliances are present in a household then probability of certain other appliances being present may be inferred. For example, if a DVD player is present then it may be inferred that a television is present.
   (ii) Socio-economic data, seasonal data and/or geographic data that may indicate a high probability of a certain appliances being present. For example the probability of an appliance being present in a household will vary based on the nature of the household (e.g. domestic or office) and the geographic location of the household. With respect to location of the household, factors affecting the likelihood of a given appliance being present in a given household may include demographics of household residents in the area in which the household is located. Similarly, the climate in the location of the household may affect the likelihood of certain appliances being present—for instance, likelihood of heating appliances being present and in use is higher in relatively cold climates whereas likelihood of cooling appliances being present an in use is likewise higher in warmer climates.
   (iii) Behavioural data. For example, a possible match with an event series associated with operation of a lawnmower may be verified if the relevant event series occurred during the day, however the match may be discarded or accorded a lower probability of being accurate if the relevant event series occurred at night. The use of certain appliances may also vary over the course of a year and from season to season, and this variation may also be taken into account in assessing the probability of a match being correct. For example, the confidence in the accuracy of a match for a heating appliance may be higher in the winter than in the summer, and vice versa for a cooling appliance. The variation in frequency and intensity of use of such appliances over the course of a year may be taken into account. For example, a heater may be on continuously at a high power consumption level during winter months, and while it may also be on during spring months it is likely to be used less frequently and/or at a lower power consumption level.

By taking into account one or more of these further information sources it may be possible to identify an event series with a high degree of confidence in cases where matching of the event series alone gave a low probability of that appliance being present. Likewise, appliances that were assumed to be present based event matrix matching may in fact be found to be unlikely to be present or definitely not present when information from these further data sources is taken into account.

Identification of an appliance using a combination of electricity consumption data and other data is described above, however in one aspect of the invention an appliance may be matched based on a combination of measured data and inferred data in which electricity consumption data is only one possible form of measurable data that is not necessarily measured and used in order to identify an appliance. This combination may be a combination of measured data and inferred data or it may be a combination of two or more different types of measured data such as temperature and water consumption.

Moreover, it will be appreciated that use of these other data sources can provide information on consumption not only of electricity but also of other utilities, in particular gas and water.

### User Input

A library of matching appliances within a household identified using the measured data and/or inferred data may be communicated to the appliance user(s), in particular to a website that the user may access, who may then verify the accuracy of the contents of the library. In particular, the user may confirm the presence of identified appliances, advise if an appliance is missing from the list, or advise if an item that appears on the list is in fact not present in the household. The contents of the library are thereby verified and updated.

### Apparatus

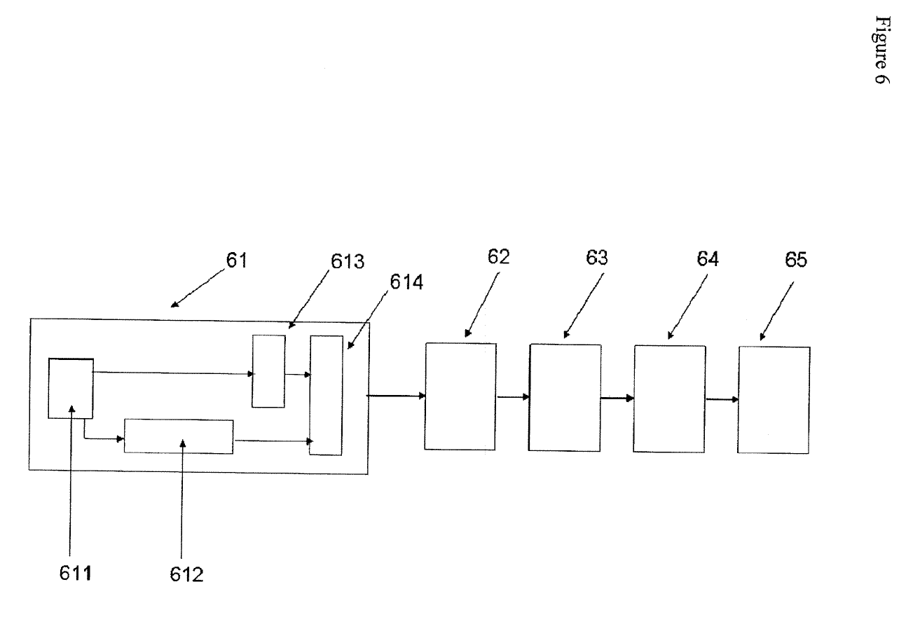

FIG. 6 illustrates apparatus for implementation of the method of the present invention comprising a sensor 61, a display 62, an uploader 63 and a back end 64.

Sensor 61 comprises an electricity measurement unit 611 and may be as described in WO 2008/142431.

The periodically measured values of real power (RP) and reactive power (REP) from the measurement unit 611 and associated time stamps are fed to a processor 612 where the compression code is applied using software running on the processor. Alternatively, the compression may be carried out by hardware in the form of an application specific integrated circuit (ASIC) in the sensor. Separately, for each time point the following measurements are fed from the measurement unit 611 into a control register 613 that that controls the sensor set-up, in particular the sensor sampling rate:
power readings at each time point
cumulative energy at each time point
Energy total for a time period (e.g. 24 hours), and maximum and minimum energy consumption during that time period.

The measured data is communicated wirelessly using communication means 614 to a portable user display 62, and from there via wired or wireless communication to a user's PC 63.

It will be appreciated that the compression of real and reactive power data dramatically reduces the amount of information communicated between components.

An uploader application installed on the user's PC 63 conducts a serial number check to determine which household the information originates from and then transfers the uploaded data via a network to a server 64 where time stamps associated with the measured data are used to give the actual time of day when measurements were made.

Finally, the back end 65 comprises an event identification device for processing the compressed data in order to identify events using the matching process described above.

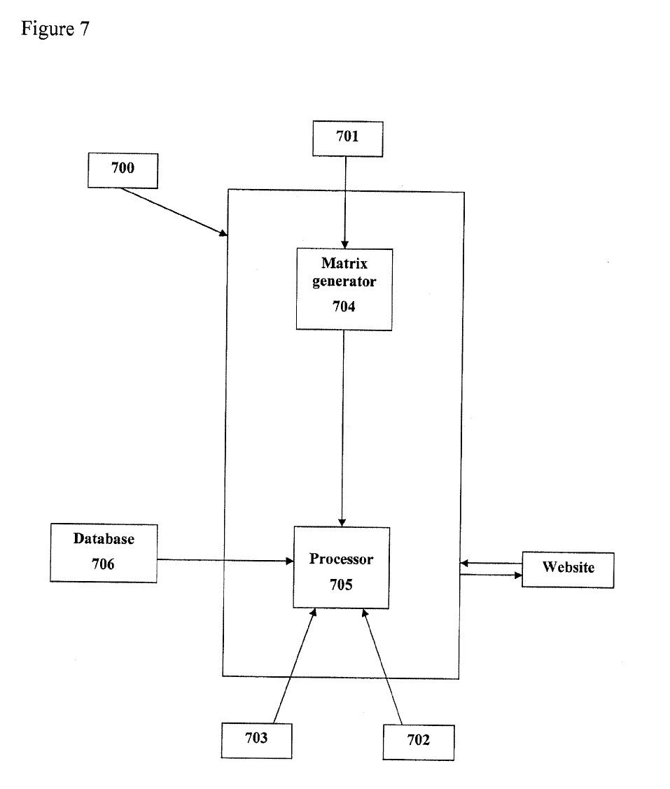

The event identification device is described in more detail in FIG. 7. The compressed electricity consumption data 701 is fed to event identification device 700 where a matrix generator 704 forms a matrix of the data. This matrix is compared by processor 705 to matrices of event series contained in a database 706 in order to identify an event in the database matching the measured event. A match may be identified based solely on analysis of the electricity consumption data, however other data sources may be used to verify the accuracy of the match. These other data sources may be:
Measured data 702, in particular data relating to consumption of other utilities. Data relating to consumption of other utilities may be compressed and provided in the form of a matrix in the same way as electricity consumption data, and compared to utility consumption profiles stored in database 706 or another database.
Facts 703 regarding the household, for example facts provided by an occupier of the household regarding appliances present in the household.
Probability data, for example the probability of a candidate appliance being in operation at the measured time of day. This probability data may be stored in database 706 or another database.

Processors 705 can take account of these further information sources in order to verify the accuracy of a match, or to discard a match if that match is incompatible with information from other data sources.

FIG. 6 illustrates a system wherein electricity consumption is measured and electricity consumption data is compressed and transmitted via user display 62 to an event identification device. In an alternative embodiment, measurement of electricity consumption, compression of electricity consumption data and event identification may take place within a single device, for example a device in communication with database 706, thus reducing or eliminating the need for a user to upload data transmitted from the sensor.

### Use of Identified Events

The identified events can be used to populate a library of appliances for that household and, upon first use of the event identification device, this library may be communicated via a website to the user's PC for verification by the user of appliances identified within the household, and to illustrate to the user the patterns of usage and energy consumption by those appliances. Following this initial communication of the library, updates to the library may also be communicated to the user, for example if removal or addition of an appliance to the household is identified.

In addition, other measured data that was not used to form an event matrix such as energy consumed over the course of a day and minima and maxima in energy usage over the course of a day can be communicated to the user to provide a detailed picture of energy consumption within the household over the course of a day. The changes in energy usage over the course of a day can be linked to the appliances that were detected in operation during those times to provide the user with detailed energy consumption information, and the effect of different appliances on electricity consumption. Alternatively, or additionally, this data can be supplied to a utility provider or other party for analysis of the data for that single household alone, or in combination with data from one or more further households forming a database from which information such as behavioural patterns of users may be determined.

This data can be used to provide a very detailed picture of utility consumption within a household, including the time and frequency of use of appliances.

A target for energy consumption may be set using the measured data, either alone or in combination with other data such as by comparison with average consumption of other households or peer groups. In addition to setting a target for energy consumption, the data could be used to suggest behavioural changes, such as turning off devices that do not appear to be in active use or reducing use of appliances that are used more frequently than average.

Measured data may also be used to identify faulty appliances. For example, operation of an faulty appliance may give the same event series as a normal appliance but with higher power levels. A user may therefore be alerted to a potential fault in the appliance.

In addition to providing data that can be used to review and adjust consumption of utilities, the measured data may also be used to provide healthcare services. For example, a service may be provided to vulnerable individuals such as the elderly and/or individuals that live alone wherein the detection of a significant change in consumption of utilities triggers an alert to check on the wellbeing of those individuals. The significant change may be the occurrence or absence of a specific detectable event, such as a failure to detect use of a specific appliance within a specific time period, or a failure to detect use of any appliances at all for a specified length of time and/or within a specified time period.

The invention has been discussed primarily with respect to consumption of electricity, however it will be appreciated that the methods described herein can equally be applied to consumption of water or gas supplied to a household. For example, with respect to water it will be appreciated that operation of a washing machine or dishwasher will include identifiable water consumption event series. Moreover, other events such as use of a garden hose may be determined based on the volume of water and water flow rate. Each of these events may be verified using other data, such as time of use (for example, an event series that appears to be indicative of use of a garden hose may be given a lower probability of being accurate if it takes place at night). In this way, consumption of water and gas can be monitored and adjusted based on the data generated. Likewise, this data can provide other services, such as healthcare monitoring, either alone or in combination with electricity consumption data.

As shown by the above discussion, functions relating to the identification of an event using utility consumption data may be implemented on computers connected for data communication via the components of a packet data network. Although special purpose devices may be used, such devices also may be implemented using one or more hardware platforms intended to represent a general class of data processing device commonly used so as to implement the event identification functions discussed above, albeit with an appropriate network connection for data communication.

As known in the data processing and communications arts, a general-purpose computer typically comprises a central processor or other processing device, an internal communication bus, various types of memory or storage media (RAM, ROM, EEPROM, cache memory, disk drives etc.) for code and data storage, and one or more network interface cards or ports for communication purposes. The software functionalities involve programming, including executable code as well as associated stored data, e.g. files of known event profiles used for matching to a measured event profile. The software code is executable by the general-purpose computer that functions as the server or terminal device used for event identification. In operation, the code is stored within the general-purpose computer platform. At other times, however, the software may be stored at other locations and/or transported for loading into the appropriate general-purpose computer system. Execution of such code by a processor of the computer platform or by a number of computer platforms enables the platform(s) to implement the methodology for event identification, in essentially the manner performed in the implementations discussed and illustrated herein.

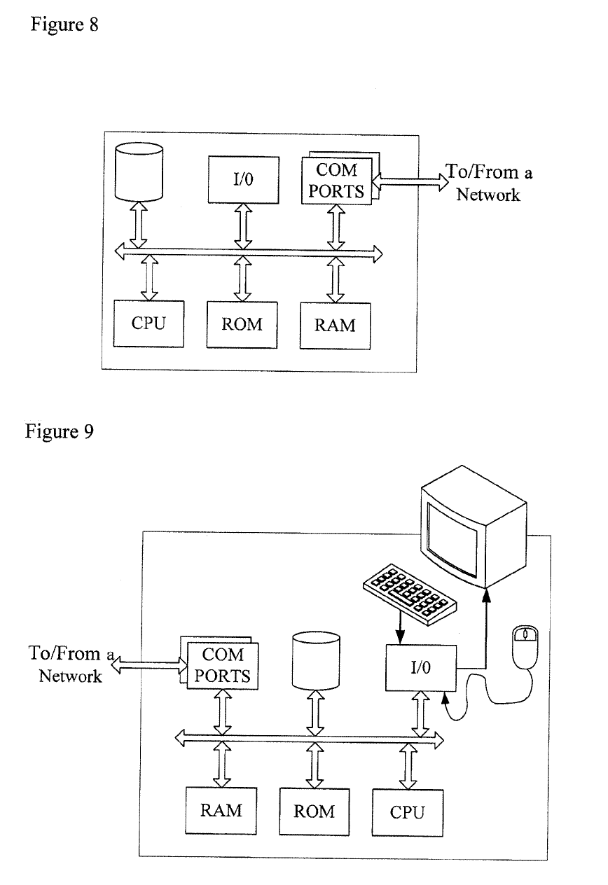

FIGS. 8 and 9 provide functional block diagram illustrations of general purpose computer hardware platforms. FIG. 8 illustrates a network or host computer platform, as may typically be used to implement a server. FIG. 9 depicts a computer with user interface elements, as may be used to implement a personal computer or other type of work station or terminal device, although the computer of FIG. 9 may also act as a server if appropriately programmed. It is believed that those skilled in the art are familiar with the structure, programming and general operation of such computer equipment and as a result the drawings should be self-explanatory.

A server, for example, includes a data communication interface for packet data communication. The server also includes a central processing unit (CPU), in the form of one or more processors, for executing program instructions. The server platform typically includes an internal communication bus, program storage and data storage for various data files to be processed and/or communicated by the server, although the server often receives programming and data via network communications. The user terminal computer will include user interface elements for input and output, in addition to elements generally similar to those of the server computer, although the precise type, size, capacity, etc. of the respective elements will often different between server and client terminal computers. The hardware elements, operating systems and programming languages of such servers are conventional in nature, and it is presumed that those skilled in the art are adequately familiar therewith. Of course, the server functions may be implemented in a distributed fashion on a number of similar platforms, to distribute the processing load.

Hence, aspects of the methods of event identification outlined above may be embodied in programming. Program aspects of the technology may be thought of as “products” or “articles of manufacture” typically in the form of executable code and/or associated data that is carried on or embodied in a type of machine readable medium and/or in a plurality of such media. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the organisation providing event identification services into the event identification computer platform. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the event identification, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media can take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer can read programming code and/or data. Many of these forms of computer readable media may be involved in carrying one or more sequences of one or more instructions to a processor for execution.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

1) A method of identifying an event associated with consumption of a utility comprising the steps of:
generating a utility consumption profile from utility consumption data, the utility consumption data comprising a plurality of utility consumption values measured at a corresponding plurality of measurement points; and
identifying an event within the utility consumption profile that matches the profile of an event stored in a database of utility consumption profiles.

2) A method according to claim 1 wherein the utility is selected from gas, electricity and water.

3) A method according to claim 2 wherein the utility is electricity.

4) A method according to claim 3 wherein the measured electricity consumption data includes data of real power.

5) A method according to claim 3 wherein the measured electricity consumption data includes data of reactive power.

6) A method according to claim 3 wherein the measured electricity consumption data includes data of reactive power and real power.

7) A method according to claim 2 wherein the utility is water.

8) A method according to claim 1 wherein the plurality of measurement points are a plurality of time points with intervals therebetween.

9) A method according to claim 8 wherein the intervals between time points is in the range 0.01-60 seconds.

10) A method according to claim 1 wherein generating the utility consumption profile comprises the step of determining a gradient of rate of change of utility consumption between consecutive measurement points; identifying measurement points at which a change in gradient exceeds a predetermined threshold; and storing in the utility consumption profile the utility consumption value at measurement points where the threshold is exceeded.

11) A method according to claim 1 wherein the matching of the utility consumption profile comprises representing the utility consumption profile in the form of a matrix and matching the contents of the matrix to utility consumption event profile matrices stored in the database.

12) A method according to claim 11 wherein one or more entries in the matrix are weighted.

13) A method according to claim 11 wherein a match is identified if the extent of matching between a series of entries in a measured matrix and a matrix stored in the database exceeds a threshold value.

14) A method according to claim 11 wherein the utility consumption profile is disaggregated.

15) A method according to claim 1 wherein the generated utility consumption profile is analysed to identify an event matching a utility consumption profile stored in the database and associated with operation of an appliance that consumes the utility.

16) A method according to claim 15 wherein the generated and stored utility consumption profiles are electricity consumption profiles and the appliance is an electrical appliance.

17) A method according to claim 1 wherein the utility consumption data is one of gas, electricity and water consumption data, and the identity of the event is verified using at least one of the other of gas, electricity and water consumption data.

18) A method according to claim 1 wherein the identity of the event is verified using measured data other than utility consumption data.

19) A method according to claim 18 wherein the measured data is temperature data.

20) A method according to claim 1 wherein the identity of the event is verified using probability data.

21) A method according to claim 1 wherein the identity of an event associated with an appliance is verified using data supplied by an appliance user.

22) Computer program code which when run on a computer causes the computer to perform the method according to claim 1.

23) A carrier medium carrying computer readable code which when run on a computer causes the computer to perform the method according to claim 1.

24) A computer program product comprising computer readable code according to claim 23.

25) Computer-implemented event identification apparatus comprising:
a profile generator for generating a utility consumption profile from utility consumption data, the utility consumption data comprising a plurality of utility consumption values measured at a corresponding plurality of time points; and
an event identifier for identifying an event within the utility consumption profile that matches the profile of an event stored in a database of utility consumption profiles.

26) An article of manufacture comprising:
a machine-readable storage medium; and
executable program instructions embodied in the machine readable storage medium that when executed by a programmable system causes the system to perform the function of identifying an event associated with consumption of a utility comprising the steps of:
generating a utility consumption profile from utility consumption data, the utility consumption data comprising a plurality of utility consumption values measured at a corresponding plurality of measurement points; and
identifying an event within the utility consumption profile that matches the profile of an event stored in a database of utility consumption profiles.

27) A method of compressing utility consumption data comprising a plurality of utility consumption values at a corresponding plurality of measurement points comprising: determining a gradient of change of utility consumption value between each consecutive measurement point, and identifying and storing measurement points where a change in the gradient exceeds a threshold value.

28) A method according to claim 27 wherein the utility consumption data is electrical power demand data; the plurality of utility consumption values are power values; and the plurality of measurement points regularly spaced time points.

29) A method according to claim 28 wherein the electrical power demand data is real power and/or reactive power.

30) A device for compressing utility consumption data comprising a plurality of utility consumption values at a corresponding plurality of measurement points, the device comprising:
means for determining a gradient of change of utility consumption value between each consecutive measurement point, and
means for identifying and storing measurement points where a change in the gradient exceeds a threshold value.

31) A device according to claim 30 further comprising means for measuring utility consumption to generate utility consumption data.

32) A device according to claim 30, further comprising means for wired or wireless transmission of compressed utility consumption data to a data processor.

33) An integrated circuit configured to perform the steps according to claim 27.

34) Computer program code which when run on a computer causes the computer to perform the method according to claim 27.

35) A computer program product carrying program code according to claim 34.

36) A carrier medium carrying computer readable code which when run on a computer causes the computer to perform the method according to claim 27.

37) An article of manufacture comprising:
a machine-readable storage medium; and
executable program instructions embodied in the machine readable storage medium that when executed by a programmable system causes the system to perform the function of compressing utility consumption data, comprising the steps of:
determining a gradient of change of utility consumption value between each consecutive measurement point, and
identifying and storing measurement points where a change in the gradient exceeds a threshold value.

38) A method of identifying an appliance comprising the steps of:
identifying a candidate appliance by matching utility consumption of known appliances stored in a database to measured consumption of a first utility; and
comparing a known property of the candidate appliance to a property of the measured appliance to verify the accuracy of the match.

39) A method according to claim 38 wherein the known property of the appliance is the utility consumption of a second utility, the second utility being different from the first utility.

40) A method according to claim 38 wherein the first and second utilities are selected from water, gas and electricity.

41) A method according to claim 38 wherein the known property of the candidate appliance is probability data associated with the candidate appliance.

42) Computer implemented apparatus comprising:
means for identifying a candidate appliance by matching utility consumption of known appliances stored in a database to measured consumption of a first utility;
means for identifying a second property of an appliance; and
means for comparing a known property of the candidate appliance to a property of the measured appliance to verify the accuracy of the match.

43) An article of manufacture comprising:
a machine-readable storage medium; and
executable program instructions embodied in the machine readable storage medium that when executed by a programmable system causes the system to perform the function of identifying an appliance, comprising the steps of:
identifying a candidate appliance by matching utility consumption of known appliances stored in a database to measured consumption of a first utility; and
comparing a known property of the candidate appliance to a property of the measured appliance to verify the accuracy of the match.

44) Computer program code which when run on a computer causes the computer to perform the method according to claim 38.

45) A computer program product carrying program code according to claim 44.

46) A carrier medium carrying computer readable code which when run on a computer causes the computer to perform the method according to claim 38.
